(19) United States
(12) Patent Application Publication
(10) Pub. No.: US 2025/0308864 A1
(43) Pub. Date: Oct. 2, 2025

(54) SUBSTRATE PROCESSING METHOD, SUBSTRATE PROCESSING APPARATUS, AND SUBSTRATE PROCESSING SYSTEM

(71) Applicant: Tokyo Electron Limited, Tokyo (JP)

(72) Inventors: Atsushi KAWABATA, Kurokawa-gun (JP); Masaaki MIYAGAWA, Tokyo (JP); Chong SAI, Kurokawa-gun (JP)

(73) Assignee: Tokyo Electron Limited, Tokyo (JP)

(21) Appl. No.: 19/234,971

(22) Filed: Jun. 11, 2025

Related U.S. Application Data
(63) Continuation of application No. PCT/JP2023/044527, filed on Dec. 12, 2023.

(30) Foreign Application Priority Data
Dec. 21, 2022 (JP) 2022-204339

(51) Int. Cl. H01J 37/32

(52) U.S. Cl. CPC H01J 37/32724; H01J 37/32697; H01J 37/32889; H01J 2237/334

(57) ABSTRACT

A disclosed substrate processing method includes placing a substrate on an electrostatic chuck of a substrate support of a substrate processing apparatus. The electrostatic chuck includes a substrate support surface. The substrate includes a back surface and an organic layer formed in advance on the back surface. The substrate is placed on the electrostatic chuck so that the organic layer is in contact with the substrate support surface. The substrate processing method further includes operating the electrostatic chuck to hold the substrate by electrostatic attraction. The substrate processing method further includes processing the substrate in the substrate processing apparatus.

### CROSS-REFERENCE TO RELATED APPLICATIONS

This application is a continuation application of PCT Application No. PCT/JP2023/044527, filed on Dec. 12, 2023, which claims the benefit of priority from Japanese Patent Application No. 2022-204339, filed on Dec. 21, 2022. The entire contents of the above listed PCT and priority applications are incorporated herein by reference.

### BACKGROUND

### Field

Example embodiments of the present disclosure relate to a substrate processing system.

### Description of the Related Art

A substrate processing apparatus is used for processing substrates. The substrate processing apparatus includes a chamber and a substrate support. The substrate support is disposed in the chamber. Japanese Unexamined Patent Application Publication (Translation of PCT Application) No. 2007-527625 discloses a technique of providing a diamond-like coating on a surface of the substrate support.

### SUMMARY

A substrate processing method is provided in an example embodiment. The substrate processing method includes placing a substrate on an electrostatic chuck of a substrate support of a substrate processing apparatus. The electrostatic chuck includes a substrate support surface. The substrate includes a back surface and an organic layer formed in advance on the back surface. The substrate is placed on the electrostatic chuck so that the organic layer is in contact with the substrate support surface. The substrate processing method further includes operating the electrostatic chuck to hold the substrate by electrostatic attraction. The substrate processing method further includes processing the substrate in the substrate processing apparatus.

### BRIEF DESCRIPTION OF THE DRAWINGS

FIG. 1 is a diagram for illustrating an example configuration of a plasma processing system.

FIG. 2 is a diagram for illustrating an example configuration of a capacitively coupled plasma processing apparatus.

FIG. 3 is a cross-sectional view illustrating a substrate support according to one example embodiment.

FIG. 4 is a cross-sectional view illustrating a substrate support according to one example embodiment.

FIG. 5 is a flowchart illustrating a substrate processing method according to one example embodiment.

FIG. 6 is a cross-sectional view of a substrate according to one example embodiment.

FIG. 7A to FIG. 7D are each diagrams illustrating examples of structural formulae of an organic layer WL.

FIG. 8 is a flowchart illustrating a substrate processing method according to another example embodiment.

FIG. 9 is a diagram illustrating a substrate processing system according to one example embodiment.

FIG. 10 is a diagram illustrating a film forming apparatus according to one example embodiment.

FIG. 11 is a diagram illustrating a removal apparatus according to one example embodiment.

FIG. 12 is a flowchart illustrating a substrate processing method according to still another example embodiment.

FIG. 13 is a diagram illustrating substrate processing equipment according to another example embodiment.

FIG. 14 is a diagram illustrating substrate processing equipment according to still another example embodiment.

FIG. 15 is a cross-sectional view illustrating a substrate support according to another example embodiment.

### DETAILED DESCRIPTION

Hereinafter, various example embodiments will be described in detail with reference to the drawings. In the drawings, the same or equivalent portions are denoted by the same reference symbols.

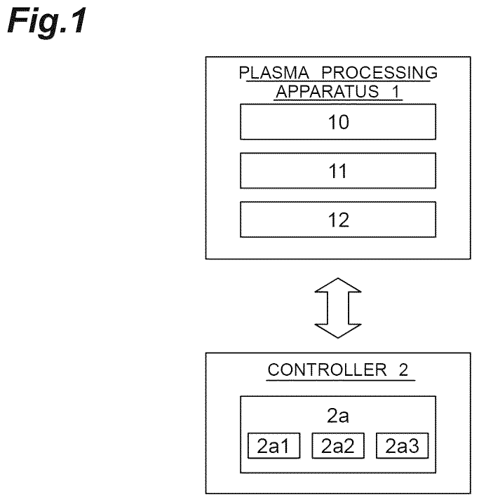

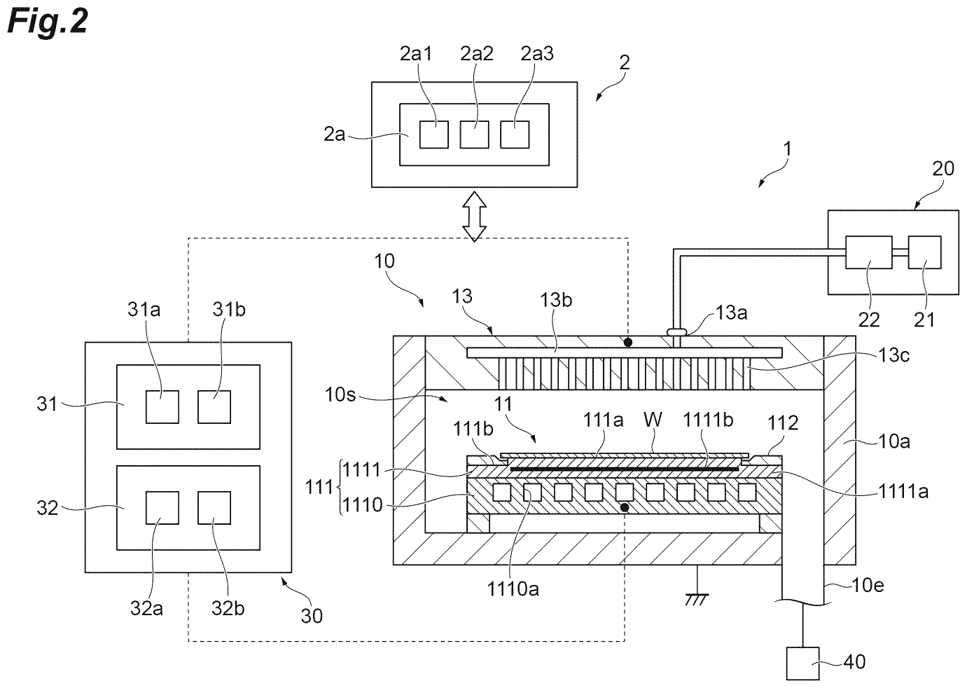

First, a plasma processing apparatus, which is a substrate processing apparatus according to one example embodiment, will be described with reference to FIGS. 1 and 2.

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate support surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps described herein. In an embodiment, the functions of the controller 2 may be partially or entirely incorporated into the plasma processing apparatus 1. The controller 2 may include a processor 2al, a storage 2a2, and a communication interface 2a3. The controller 2 is implemented in, for example, a computer 2a. The processor 2al may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2al reads to execute the program from the storage 2a2. The medium may be of any type which can be accessed by the computer 2a or may be a communication line connected to the communication interface 2a3. The processor 2al may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate support surface for supporting the substrate W, while the annular region 111b is also called a ring support surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulting member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 1110 and the at least one RF/DC electrode may function as a plurality of lower electrodes. The electrostatic electrode 1111b may also be function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

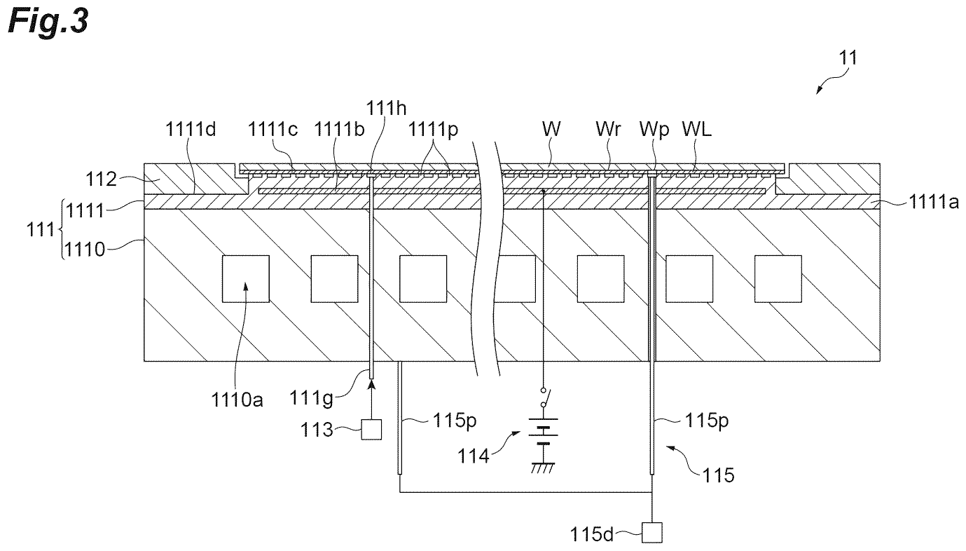

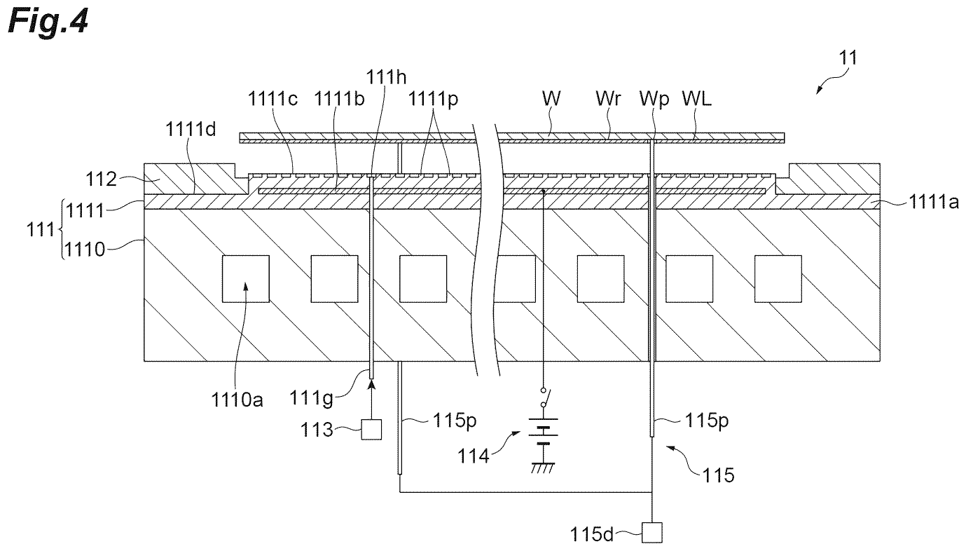

In the following, the description will be made with reference to FIGS. 3 and 4 together with FIG. 2. Each of FIGS. 3 and 4 is a cross-sectional view illustrating a substrate support according to one example embodiment. The substrate support 11 includes the electrostatic chuck 1111 as described above. As illustrated in FIGS. 3 and 4, the electrostatic chuck 1111 includes a substrate support surface 1111c and a ring support surface 1111d. The substrate support surface 1111c is the central region 111a described above. The substrate support surface 1111c is configured by top surfaces of a plurality of protrusions 1111p that protrude upward in the electrostatic chuck 1111. The substrate W has an organic layer WL formed in advance on a back surface Wr thereof, as will be described later. The substrate W is placed on the electrostatic chuck 1111 so that the organic layer WL is in contact with the substrate support surface 1111c. In a state in which the substrate W is placed on the electrostatic chuck 1111, the plurality of protrusions 1111p provide gaps between the plurality of protrusions 1111p and between the substrate W and an upper surface of the electrostatic chuck 1111.

The substrate support 11 may further include a gas supply line 111g for supplying a heat transfer gas, such as He gas, to the gap between the substrate W and the upper surface of the electrostatic chuck 1111. A heat transfer gas supply 113 is connected to the gas supply line 111g. The gas supply line 111g provides a gas supply port 111h at an upper end thereof. The gas supply port 111h is open toward the gap between the substrate W and the upper surface of the electrostatic chuck 1111.

The electrostatic electrode 1111b of the electrostatic chuck 1111 is disposed between the substrate support surface 1111c and a lower surface of the electrostatic chuck 1111. A DC power supply 114 is connected to the electrostatic electrode 1111b via a switch.

The plasma processing apparatus 1 may further include a support body 115. The support body 115 is configured to be movable up and down with respect to the substrate support surface 1111c and to support the substrate W at a position spaced above the substrate support surface 1111c. The support body 115 may include a plurality of lifter pins 115p. The plurality of lifter pins 115p are inserted into through holes formed in a body 111 of the substrate support 11. The plurality of lifter pins 115p are moved up and down by a driving unit 115d.

As illustrated in FIG. 4, tip ends of the plurality of lifter pins 115p abut on the substrate W in a case where the tip ends are located above the substrate support surface 1111c. As a result, the support body 115 supports the substrate W at a position spaced above the substrate support surface 1111c. In a case where the organic layer WL is formed on the entire back surface Wr of the substrate W, the tip ends of the plurality of lifter pins 115p abut on the organic layer WL. Alternatively, the organic layer WL may be formed in a region other than a plurality of regions Wp in the back surface Wr of the substrate W on which the support body 115 (the tip ends of the plurality of lifter pins 115p) abut, or may not be formed in the plurality of regions Wp. In this case, the support body 115 (the tip ends of the plurality of lifter pins 115p) abut on the plurality of regions Wp of the back surface Wr of the substrate W.

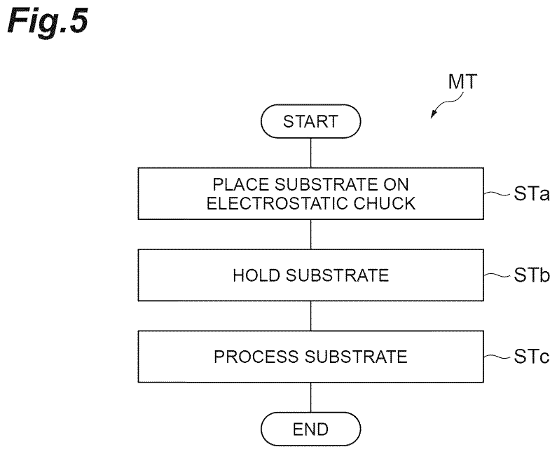

In the following, a substrate processing method according to one example embodiment will be described with reference to FIG. 5. Each step of the substrate processing method illustrated in FIG. 5 (hereinafter, referred to as a “method MT”) may be performed by the control of the controller 2 with respect to each part of the plasma processing apparatus 1.

The substrate processing method illustrated in FIG. 5 (hereinafter, referred to as a “method MT”) starts with Step STa. In Step STa, the substrate W is placed on the electrostatic chuck 1111. As described above, the substrate W includes the back surface Wr and the organic layer WL. The organic layer WL is formed in advance on the back surface Wr. The organic layer WL can have a friction coefficient lower than a friction coefficient of the back surface Wr of the substrate W.

The organic layer WL may be formed on the entire back surface Wr. Alternatively, the organic layer WL may be partially formed on the back surface Wr. For example, the organic layer WL may not be formed in the central region of the back surface Wr, and may be formed in an outer region of the back surface Wr. The outer region of the back surface Wr includes an edge of the back surface Wr. In this case, the organic layer WL having a low friction coefficient is present in a region where significant friction may occur with respect to the substrate support surface 1111c. Therefore, the damage to the back surface Wr of the substrate W and the wear and damage to the substrate support surface 1111c in such a region are suppressed.

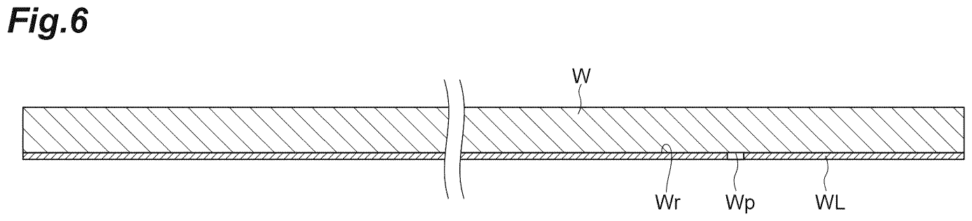

FIG. 6 is a cross-sectional view of a substrate according to one example embodiment. As illustrated in FIG. 6, the organic layer WL may not be formed in the plurality of regions Wp described above. The support body 115 (the tip ends of the plurality of lifter pins 115p) abut on the plurality of regions Wp in a case where the substrate W is supported above the substrate support surface 1111c in a substrate processing apparatus such as a plasma processing apparatus 1 used in Step STc which will be described later. Since the regions Wp have a relatively high friction coefficient, the position of the substrate W on the support body 115 (the tip ends of the plurality of lifter pins 115p) is suppressed from being shifted by slipping.

In addition, the organic layer WL may not be formed in a region of the back surface Wr with which a pick of a transfer device (for example, various transfer robots described later) comes into contact during transfer of the substrate W. In this case, the positional shift due to the slipping of the substrate W with respect to the pick is suppressed.

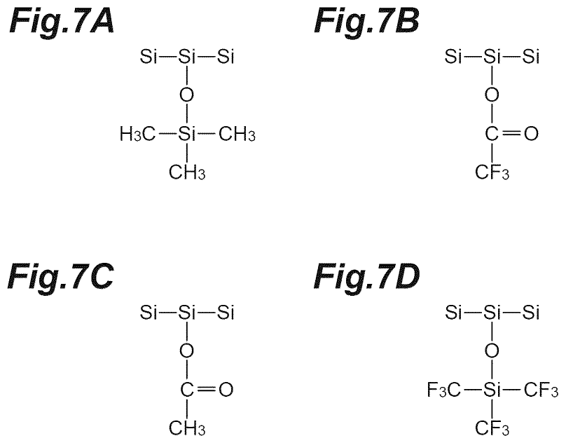

Each of FIG. 7A to FIG. 7D is a diagram illustrating an example of a structural formula of the organic layer. As illustrated in FIG. 7A to FIG. 7D, the organic layer WL is formed by replacing hydrogen of a silanol group (Si—OH) on the back surface Wr of the substrate W with a carbon-containing group R to convert the silanol group into Si—OR. The carbon-containing group R may be a hydrophobic group containing carbon. The organic layer WL may contain carbon or may contain silicon and carbon. In addition, the organic layer WL may be a monomolecular layer.

As illustrated in FIG. 7A, the organic layer WL may contain silicon and oxygen. The organic layer WL may contain a trimethylsilyl group. In this case, the organic layer WL is formed by supplying a film forming gas including 1,1,1,3,3,3-hexamethyldisilazane (HMDS) to the back surface Wr of the substrate W. The film forming gas only needs to be any gas as long as it can convert the silanol group of the back surface Wr into Si—OR. For example, the film forming gas may be a gas including a non-silane agent such as dimethyl carbonate and/or di(trifluoromethyl) carbonate, and the organic layer WL obtained in this case may include a trifluoroacetyl group as illustrated in FIG. 7B or may include an acetyl group as illustrated in FIG. 7C. In addition, the film forming gas may be a silazane containing fluorine, and the organic layer WL obtained in this case may include a tris(trifluoromethyl) group as illustrated in FIG. 7D. In addition, the film forming gas is not limited to a gas containing a silane coupling agent or dimethyl carbonate as long as the friction coefficient of the organic layer WL can be made smaller than the friction coefficient of the back surface Wr.

In Step STa, the substrate W is placed on the electrostatic chuck 1111 so that the organic layer WL is in contact with the substrate support surface 1111c. In Step STa, the driving unit 115d may be controlled to place the substrate W on the substrate support surface 1111c.

Next, in the method MT, Step STb is performed. In Step STb, the substrate W is held (fixed) by the electrostatic chuck 1111 by electrostatic attraction of the electrostatic chuck 1111. In Step STb, a voltage is applied to the electrostatic electrode 1111b in order to hold the substrate W.

Next, in the method MT, Step STc is performed. Step STc is performed in a state in which the substrate W is held by the electrostatic chuck 1111. In Step STc, the substrate W is processed in the chamber 10. The processing on the substrate W may be etching or plasma etching on the substrate W. In this case, the plasma processing apparatus 1 is an etching apparatus. In Step STc, the gas supply 20 is controlled to supply the process gas into the chamber 10. In addition, the exhaust system 40 is controlled to adjust the pressure in the chamber 10 to a designated pressure. In Step STc, the power supply 30 may be controlled to supply a first RF signal and/or a second RF signal in order to generate plasma.

In the method MT, the substrate W is held by the electrostatic chuck 1111 in a state in which the organic layer WL is in contact with the substrate support surface 1111c. Since the organic layer WL has a low friction coefficient, damage to the back surface Wr of the substrate W is suppressed in a case where the substrate W is held by the electrostatic chuck 1111. In addition, the wear and the damage of the substrate support surface 1111c are suppressed. As a result, the generation of particles is suppressed. The damage to the back surface Wr of the substrate W and the wear and damage of the substrate support surface 1111c include ones caused by sliding between the back surface Wr of the substrate W and the substrate support surface 1111c based on heat input from the plasma, a change in the set temperature of the substrate W, or thermal expansion and contraction caused by both.

In addition, according to the organic layer WL, the fluctuation in the contact area between the substrate W and the substrate support surface 1111c is suppressed. Therefore, leakage of the heat transfer gas due to the wear and/or damage of the substrate support surface 1111c is suppressed. Therefore, the fluctuations in a cooling efficiency of the substrate W are suppressed.

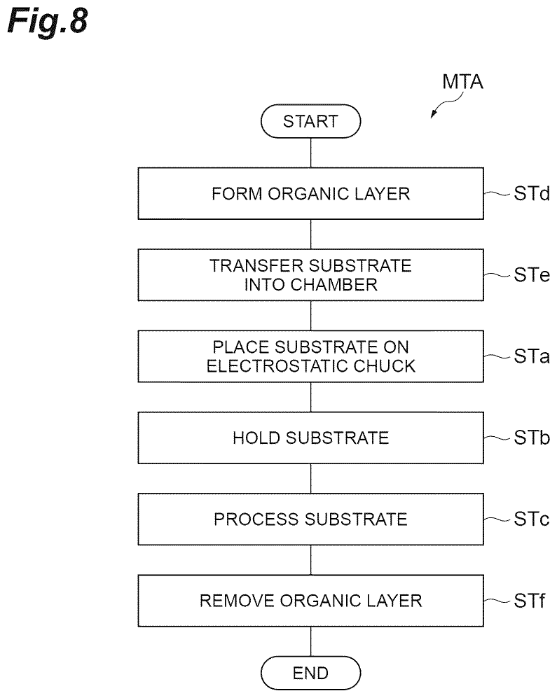

In the following, a substrate processing method according to another example embodiment will be described with reference to FIG. 8. FIG. 8 is a flowchart illustrating a substrate processing method according to another example embodiment. In the following, the substrate processing method illustrated in FIG. 8 (hereinafter, referred to as a “method MTA”) will be described from the viewpoint of differences from the method MT. The method MTA is performed in the substrate processing system.

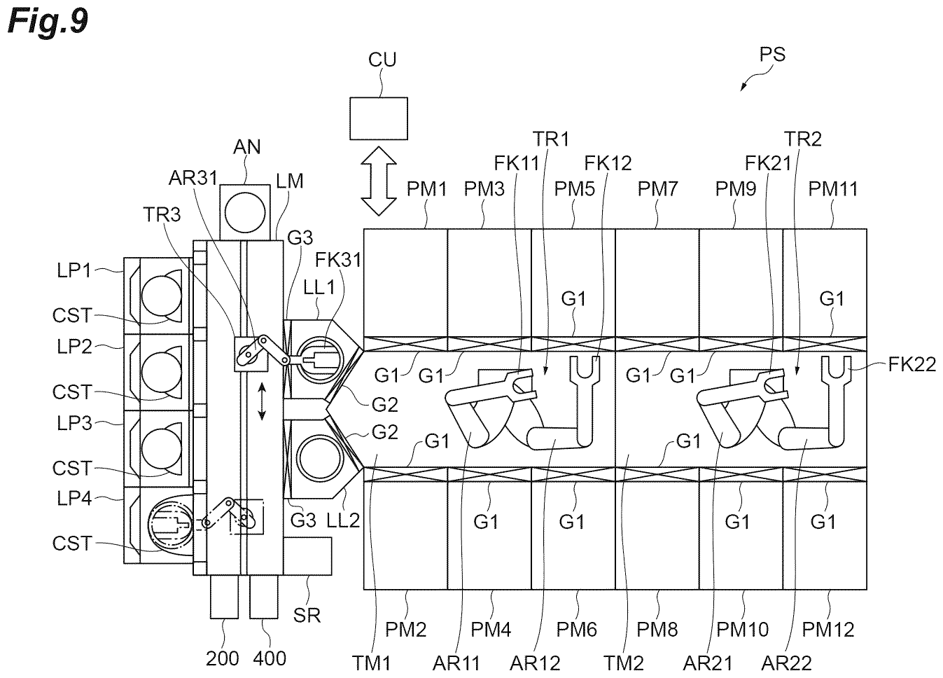

FIG. 9 is a diagram illustrating a substrate processing system according to one example embodiment. A substrate processing system PS illustrated in FIG. 9 may be used in the method MTA. The substrate processing system PS includes a loader module LM, an aligner AN, a storage SR, load lock modules LL1 and LL2, transfer modules TM1 and TM2, process modules PM1 to PM12, and the like.

The loader module LM includes a chamber. A pressure in the chamber of the loader module LM is set to an atmospheric pressure. The loader module LM may have a fan filter unit (FFU). The loader module LM is, for example, an equipment front end module (EFEM). The loader module LM is disposed between each of load ports LP1 to LP4 and each of the load lock modules LL1 and LL2. The load ports LP1 to LP4 are arranged along one of a pair of edges along a longitudinal direction of the loader module LM. The load lock modules LL1 and LL2 are arranged along the other of the pair of edges along the longitudinal direction of the loader module LM. Each of the load ports LP1 to LP4 is configured to support a cassette CST placed thereon. The cassette CST is a container that accommodates a plurality of substrates W therein. The cassette CST is, for example, a front-opening unified pod (FOUP).

The loader module LM further includes a transfer robot TR3. The transfer robot TR3 is disposed in a chamber of the loader module LM. The transfer robot TR3 may include a multi-joint arm AR31 and a pick FK31. The pick FK31 is attached to a tip end of the multi-joint arm AR31, and is configured to support the substrate W placed thereon. The transfer robot TR3 transfers the substrate W based on an operation instruction output from a controller CU, which will be described later. The transfer robot TR3 transfers the substrate W between any two of the cassettes CST placed on at least one of the load ports LP1 to LP4, the load lock modules LL1 and LL2, the aligner AN, and the storage SR.

The aligner AN is disposed along one of the pair of edges along a short side direction of the loader module LM. The aligner AN may be disposed along an edge along the longitudinal direction of the loader module LM. In addition, the aligner AN may be disposed in the chamber of the loader module LM. The aligner AN includes a support base, an optical sensor, and the like. The support base of the aligner AN is rotatable and supports the substrate W placed thereon. The aligner AN detects an angle position of a marker (for example, a notch) of the substrate W on the support base and a center position of the substrate W on the support base by using the optical sensor. The controller CU controls the rotation of the support base of the aligner AN such that the angle position of the marker (for example, notch) of the substrate W on the support base is corrected to a reference angle position to correct the shift amount of the angle position of the substrate W. In addition, the controller CU controls a position of the pick FK31 in a case where the substrate W is received on the pick FK31 from the aligner AN, in order to position the center of the substrate W on a predetermined position of the pick FK31.

The storage SR is disposed along an edge along the longitudinal direction of the loader module LM. The storage SR may be disposed along an edge along the short side direction of the loader module LM. In addition, the storage SR may be disposed inside the loader module LM. The storage SR is configured to accommodate the substrate W therein.

Each of the load lock modules LL1 and LL2 is disposed between the transfer module TM1 and the loader module LM. Each of the load lock modules LL1 and LL2 is provided with a preliminary decompression chamber. Each of the load lock modules LL1 and LL2 and the loader module LM are connected to each other via a gate valve G3. Each of the load lock modules LL1 and LL2 and the transfer module TM1 are connected to each other via a gate valve G2.

Each of the transfer modules TM1 and TM2 includes a chamber. Each of the transfer modules TM1 and TM2 is configured to transfer the substrate W through a decompressed space in the chamber. The chamber of the transfer module TM1 is connected to each of the load lock modules LL1 and LL2 via the gate valve G2. The process modules PM1 to PM6 are connected to the chamber of the transfer module TM1 via the gate valve G1. The chamber of the transfer module TM1 is connected to the chamber of the transfer module TM2. The process modules PM7 to PM12 are connected to the chamber of the transfer module TM2 via the gate valve G1.

The transfer module TM1 includes a transfer robot TR1 provided in the chamber of the transfer module TM1. The transfer robot TR1 may include the multi-joint arms AR11 and AR12 and the picks FK11 and FK12. The pick FK11 is attached to a tip end of the multi-joint arm AR11, and is configured to support the substrate W placed thereon. The pick FK12 is attached to a tip end of the multi-joint arm AR12, and is configured to support the substrate W placed thereon. The transfer robot TR1 transfers the substrate W based on an operation instruction output from a controller CU, which will be described later. The transfer robot TR1 holds the substrate W with picks FK11 and FK12. The transfer robot TR1 transfers the substrate W between any two of the load lock modules LL1 and LL2, the process modules PM1 to PM6, the chamber of the transfer module TM1, and a path between the chamber of the transfer module TM1 and the chamber of the transfer module TM2.

The transfer module TM2 includes a transfer robot TR2 provided in the chamber of the transfer module TM2. The transfer robot TR2 may include multi-joint arms AR21 and AR22 and picks FK21 and FK22. The pick FK21 is attached to a tip end of the multi-joint arm AR21, and is configured to support the substrate W placed thereon. The pick FK22 is attached to a tip end of the multi-joint arm AR22, and is configured to support the substrate W placed thereon. The transfer robot TR2 transfers the substrate W based on an operation instruction output from a controller CU, which will be described later. The transfer robot TR2 holds the substrate W with pick FK21 and FK22. The transfer robot TR2 transfers the substrate W between any two of the process modules PM7 to PM12 and the path described above.

Each of the process modules PM1 to PM12 is configured to perform dedicated processing on the substrate W. At least one of the process modules PM1 to PM12 is a substrate processing apparatus such as the plasma processing apparatus 1 described above.

The substrate processing system PS further includes a film forming apparatus 200 and a removal apparatus 400. The film forming apparatus 200 is an apparatus configured to form the organic layer WL on the back surface Wr of the substrate W. The removal apparatus 400 is an apparatus configured to remove the organic layer WL from the back surface Wr of the substrate W. In the example illustrated in FIG. 9, each of the film forming apparatus 200 and the removal apparatus 400 is connected to the chamber of the loader module LM. Examples of each of the film forming apparatus 200 and the removal apparatus 400 will be described later.

The controller CU is, for example, a computer. The controller CU includes a central processing unit (CPU), a random access memory (RAM), a read only memory (ROM), an auxiliary storage device, and the like. The CPU operates based on a program stored in a ROM or an auxiliary storage device and controls each part of the substrate processing system PS. Alternatively, the controller 2 may also serve as the controller CU.

The substrate processing system PS is not necessarily limited to the one illustrated in FIG. 9. For example, the number of process modules and/or the number of picks in the substrate processing system may be different from those illustrated in FIG. 9. In addition, the substrate processing system may be a system (so-called loader type system) in which a plurality of module groups, each of which includes a process module and a load lock module, are connected to a loader module. In addition, the substrate processing system may be a system (so-called cluster type system) in which two or more process modules are connected around a transfer module to surround the transfer module.

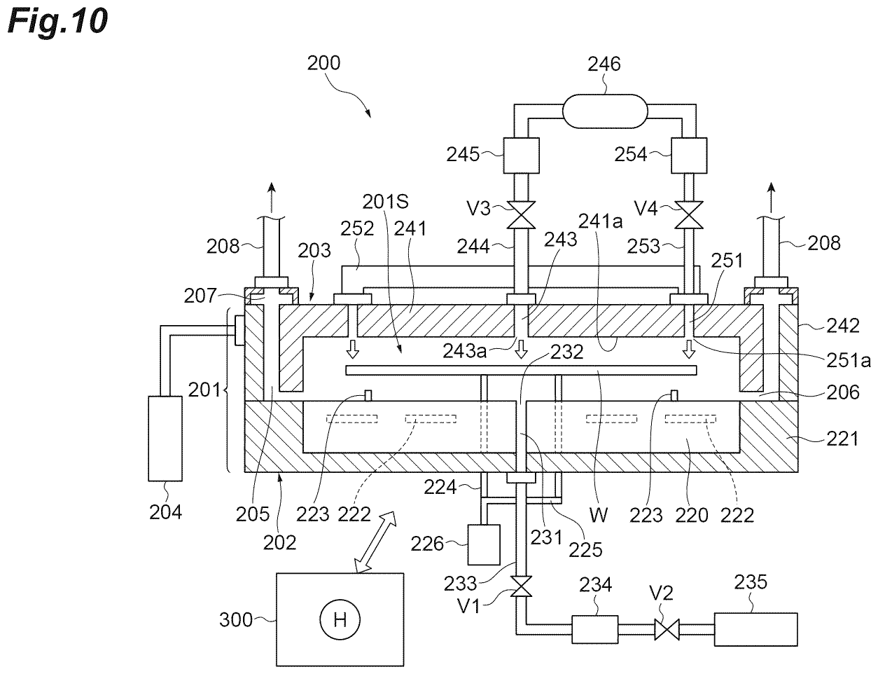

In the following, the film forming apparatus 200 will be described with reference to FIG. 10. FIG. 10 is a diagram illustrating a film forming apparatus according to one example embodiment. The film forming apparatus 200 includes a chamber 201 (film forming chamber). The chamber 201 includes a lower member 202 and an upper member 203. The lower member 202 includes a hot plate 220 and an exterior 221. The hot plate 220 has a radius larger than a radius of the substrate W. The exterior 221 has a cylindrical shape. The exterior 221 is closed at a lower end thereof and provides a space that is open upward. The hot plate 220 is disposed in the space provided by the exterior 221.

One or more heaters 222 are provided in the hot plate 220. The one or more heaters 222 are resistance heating elements. In one embodiment, the plurality of heaters 222 having an annular shape may be concentrically arranged around a central axis of the hot plate 220.

The film forming apparatus 200 further includes a plurality of gap pins 223 as a support body for supporting the substrate in the chamber 201. The plurality of gap pins 223 are disposed to protrude upward with respect to a surface of the hot plate 220. A distance between the tip end of each of the plurality of gap pins 223 and the surface of the hot plate 220 is, for example, 1 mm. The tip ends of the plurality of gap pins 223 abut on the back surface Wr of the substrate W placed thereon. The plurality of gap pins 223 may be disposed to abut on the plurality of regions Wp described above.

The film forming apparatus 200 further includes a plurality of lift pins 224. The plurality of lift pins 224 are disposed closer to the central axis of the hot plate 220 than the plurality of gap pins 223, and are disposed around the central axis of the hot plate 220 along a circumferential direction. The plurality of gap pins 223 can be vertically moved through the plurality of through holes of the hot plate 220. The plurality of lift pins 224 are connected to a lift mechanism 226.

The hot plate 220 provides a gas flow path 231. The gas flow path 231 extends on the central axis of the hot plate 220 and penetrates the hot plate 220. A tip end (upper end) of the gas flow path 231 constitutes a gas supply port 232 (third gas supply port). The gas supply port 232 is provided to be capable of supplying the film forming gas to the back surface Wr of the substrate W. The gas supply port 232 is disposed at a position facing the back surface Wr (or the center thereof) of the substrate W placed on the plurality of gap pins 223. The gas flow path 231 penetrates the exterior 221 and is connected to a gas supply pipe 233. The gas supply pipe 233 is connected to a gas source 235 via a valve V1, a flow rate regulator 234, and a valve V2. The gas source 235 is a source of the film forming gas described above. The film forming gas includes vapor of a raw material such as HMDS. The film forming gas may further include a carrier gas such as a nitrogen gas.

The upper member 203 includes a lid 241. The lid 241 has a cylindrical shape that is open at a lower end. The lid 241 is disposed to cover a space above the lower member 202. The lid 241 includes a peripheral wall 242. The peripheral wall 242 is disposed on an upper surface of the exterior 221. The lid 241 and the exterior 221 form a processing space 201S by closely contacting a lower surface of the peripheral wall 242 and the upper surface of the exterior 221 on the outside of an exhaust path 205 which will be described later. A part of the lid 241 constitutes a ceiling 241a that defines the processing space 201S from above. The lid 241 may be vertically movable by the lift mechanism 204. In a state in which the lid 241 is disposed above the exterior 221, the substrate W can be delivered between an external transfer device (for example, a transfer robot) and the plurality of lift pins 224.

The ceiling 241a provides a gas flow path 243. The gas flow path 243 extends along a central axis of the ceiling 241a and penetrates the ceiling 241a. The gas flow path 243 provides a gas supply port 243a (first gas supply port) that is open toward the processing space 201S at a lower end thereof. The gas supply port 243a is provided to be capable of supplying an inert gas toward the center of the upper surface of the substrate W. The gas supply port 243a is disposed at a position facing the center of the upper surface of the substrate W supported by the plurality of gap pins 223. An upper end of the gas flow path 243 is connected to a gas supply pipe 244. The gas supply pipe 244 is connected to a gas source 246 via a valve V3 and a flow rate regulator 245. The gas source 246 is a source of the inert gas such as nitrogen gas.

The ceiling 241a further provides a plurality of gas flow paths 251. The plurality of gas flow paths 251 are arranged around a central axis of the ceiling 241 a along the circumferential direction. The plurality of gas flow paths 251 may be arranged at equal intervals. The plurality of gas flow paths 251 penetrate the ceiling 241a. Each of the plurality of gas flow paths 251 provides a gas supply port 251a (second gas supply port) that is open toward the processing space 201S at the lower end thereof. The gas supply port 251a is provided to be capable of supplying an inert gas toward an edge region of the upper surface of the substrate W. The gas supply port 251a is provided at a position facing the edge region of the upper surface of the substrate W supported by the plurality of gap pins 223. A diameter of the gas supply port 251a of each of the plurality of gas flow paths 251 is, for example, 3 mm. In addition, an interval between the gas supply ports 251a adjacent to each other in the circumferential direction is, for example, 3 mm.

The upper end of each of the plurality of gas flow paths 251 communicates with a header 252. The header 252 is connected to a gas supply pipe 253. The gas supply pipe 253 is connected to a gas source 246 via a valve V4 and a flow rate regulator 254. As described above, the gas source 246 is a source of the inert gas such as a nitrogen gas.

The lid 241 provides a plurality of exhaust paths 205 inside the peripheral wall 242 thereof. The plurality of exhaust paths 205 extend in a vertical direction and penetrate the peripheral wall 242. The plurality of exhaust paths 205 are arranged around the central axis of the lid 241 along the circumferential direction. The plurality of exhaust paths 205 may be arranged at equal intervals. The lower surface of the peripheral wall 242 is in close contact with the upper surface of the exterior 221 on the outside of the exhaust path 205, and is spaced apart from the upper surface of the exterior 221 on the inside of the exhaust path 205. Accordingly, an annular exhaust port 206 that communicates with the exhaust path 205 is formed between the lower surface of the peripheral wall 242 and the exterior 221.

An exhaust chamber 207 is disposed in a peripheral edge of the upper surface of the lid 241. The exhaust chamber 207 extends in the circumferential direction and communicates with the exhaust path 205. A plurality of exhaust pipes 208 are connected to the exhaust chamber 207. The plurality of exhaust pipes 208 are arranged along the circumferential direction. The plurality of exhaust pipes 208 are connected to an exhaust duct at their downstream ends.

The film forming apparatus 200 may further include a controller 300. The controller 300 controls each part of the film forming apparatus 200. The controller 300 is configured by, for example, a computer including a CPU, a memory, and the like, and has a program storage. A program for controlling various types of processing in the film forming apparatus 200 is stored in the program storage. For example, the opening and closing of the valves V1 to V4, the lift mechanisms 204 and 226, and the flow rate regulators 234, 245, and 254 are controlled by the controller 300 based on the program. The program may be recorded in a computer-readable storage medium H or may be installed in the controller 300 from the storage medium H. In addition, the program may be installed via a network. The storage medium H may be temporary or non-temporary. The controller 2 may also serve as the controller 300.

In a case where the organic layer WL is formed on the back surface Wr of the substrate W in the film forming apparatus 200, first, the lid 241 is lifted, and the substrate W is transferred into the chamber 201 by an external transfer device. After that, the substrate W is delivered to the plurality of lift pins 224. Next, after the transfer device is retracted to the outside of the chamber 201, the lid 241 is lowered, and the inside of the chamber 201 is sealed.

Next, the plurality of lift pins 224 are lowered, and the substrate W is delivered from the plurality of lift pins 224 to the plurality of gap pins 223.

Then, the valves V3 and V4 are opened, and the inert gas from the gas source 246 is supplied into the chamber 201. The inert gas is supplied from the gas supply port 243a toward the center of the upper surface of the substrate W, and is supplied from the plurality of gas supply ports 251a toward an edge region of the upper surface of the substrate W. In addition, the valves V1 and V2 are opened, and the film forming gas from the gas source 235 is supplied into the chamber 201. The film forming gas is supplied from the gas supply port 232 toward the center of the back surface Wr of the substrate W, and flows in a radial direction along the back surface Wr of the substrate W. The gas in the processing space 201S is exhausted from a peripheral portion of the substrate W through the exhaust port 206. Accordingly, the organic layer WL is formed on the back surface Wr of the substrate W. In addition, during the formation of the organic layer WL, the substrate W may be heated by heat from one or more heaters 222.

The film forming apparatus 200 can suppress the film forming gas from being supplied toward the upper surface of the substrate W. Therefore, according to the film forming apparatus 200, the organic layer WL can be formed on the back surface Wr while suppressing the formation of the organic layer WL on the upper surface of the substrate W.

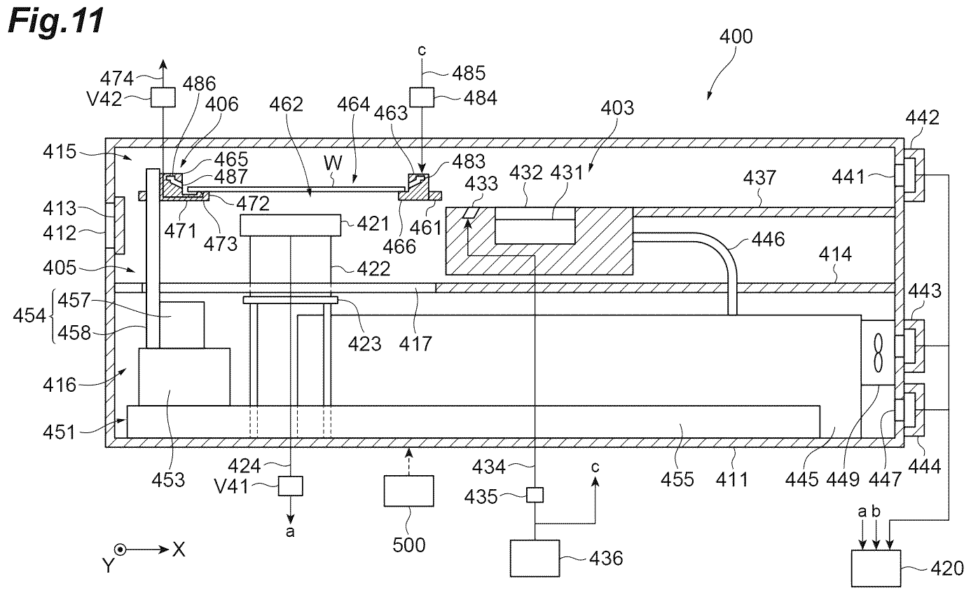

In the following, the removal apparatus 400 will be described with reference to FIG. 11. FIG. 11 is a diagram illustrating a removal apparatus according to one example embodiment. The removal apparatus 400 includes a housing 411. The housing 411 has, for example, a rectangular and horizontally long shape. The housing 411 provides a transfer port 412 in a side wall thereof extending along a short side direction. The substrate W is transferred between the inside and the outside of the housing 411 via the transfer port 412 by a transfer device (for example, a transfer robot). The transfer port 412 can be opened and closed by a shutter 413. In the following description, the longitudinal direction and the short side direction of the housing 411 are referred to as an X direction and a Y direction, respectively. In addition, a direction in which a rear end of the housing 411 is located with respect to the transfer port 412 is referred to as a rear side, and a direction opposite to the rear side is referred to as a front side.

The removal apparatus 400 further includes a spin chuck 421, a light irradiation unit 403, and a substrate holding unit 405. A space in the housing 411 is divided into an upper space 415 and a lower space 416 by a plate 414. The spin chuck 421, the light irradiation unit 403, and the substrate holding unit 405 are provided in the upper space 415.

The light irradiation unit 403 is configured to emit light upward. The organic layer WL is removed from the back surface Wr of the substrate W by irradiation with light from the light irradiation unit 403. The substrate holding unit 405 is configured to locally hold the substrate W for irradiating the organic layer WL with light and to move the substrate W through a region above the light irradiation unit 403. The spin chuck 421 is configured to mediate the delivery of the substrate W between the transfer device (or the transfer robot) and the substrate holding unit 405, and to change an orientation of the substrate W such that the substrate holding unit 405 can hold the substrate W at different positions.

The spin chuck 421 has a substantially disk shape and is disposed on the front side of the light irradiation unit 403 in the upper space 415. The upper surface of the spin chuck 421 supports the substrate W placed thereon. A suction port is open on the upper surface of the spin chuck 421. A pipe 424 is connected to the suction port. The pipe 424 is connected to an exhaust source 420 via a valve V41. The exhaust source 420 is, for example, an exhaust path of a factory in which the removal apparatus 400 is disposed, and is negative pressure with respect to atmospheric pressure. In a case where the valve V41 is opened, a central portion of the substrate W is sucked into the suction port. As a result, the substrate W is held in a horizontal state on the upper surface of the spin chuck 421. In a case where the valve V41 is closed, the suction of the substrate W is stopped.

A lower portion of the spin chuck 421 is connected to a rotation mechanism 422. A lower portion of the rotation mechanism 422 is located in the lower space 416 and is supported by a support base 423. The rotation mechanism 422 rotates around a central axis thereof. Accordingly, the spin chuck 421 is rotated, and the angle of the substrate W in the rotation direction is adjusted.

The light irradiation unit 403 is disposed on the rear side with respect to the spin chuck 421 in the upper space 415, and the light irradiation unit 403 has an ultraviolet lamp 431 therein. The upper surface of the light irradiation unit 403 includes a window 432. The window 432 may have a rectangular shape that is long in the Y direction. A length of the window 432 in the Y direction is the same as or longer than the diameter of the substrate W. A center of the window 432 in the Y direction is aligned with the center of the spin chuck 421 in the X direction. The window 432 is located above the ultraviolet lamp 431. The light emitted from the ultraviolet lamp 431 is transmitted through the window 432 and is emitted above the light irradiation unit 403. The light emitted from the window 432 is, for example, ultraviolet rays (that is, vacuum ultraviolet rays) having a wavelength in a range of 10 nm to 200 nm. The peak wavelength of the light may be 172 nm.

The upper surface of the light irradiation unit 403 is provided at a position slightly higher than the upper surface of the spin chuck 421 in the vertical direction. As a result, after the substrate holding unit 405 receives the substrate W, the window 432 and the organic layer WL of the substrate W can be brought close to each other without adjusting the position of the substrate holding unit 405 in a height direction.

The light irradiation unit 403 has a gas discharge port 433. The gas discharge port 433 has a slit shape extending in the Y direction. The gas discharge port 433 is disposed in front of the window 432. The gas discharge port 433 extends obliquely upward and rearward and is open on the upper surface of the light irradiation unit 403. A length of the gas discharge port 433 in the Y direction is longer than the length of the window 432 in the Y direction.

A downstream end of the pipe 434 is connected to the light irradiation unit 403. An upstream end of the pipe 434 is connected to a gas source 436 of a nitrogen gas via a flow rate regulator 435. The flow rate regulator 435 includes, for example, a valve and/or a mass flow controller, and adjusts the flow rate of the nitrogen gas supplied to the downstream of the pipe 434.

The nitrogen gas supplied to the pipe 434 is discharged from the gas discharge port 433. In a case where the organic layer WL of the substrate W is irradiated with light, the nitrogen gas forms an air flow that flows sideways along the lower surface of the organic layer WL. As a result, in a case where the organic layer WL of the substrate W is irradiated with light, the oxygen concentration is reduced.

A plate 437 is disposed in the housing 411. The plate 437 extends horizontally from an upper edge of the light irradiation unit 403 on the rear side toward a wall on the rear side of the housing 411. An exhaust port 441 is disposed in a wall on the rear side of the housing 411. The exhaust port 441 is open toward a space above the plate 437. Exhaust flow path forming units 442, 443, and 444 are attached to a wall on the rear side of the housing 411 from the outside. The exhaust port 441 is connected to an exhaust flow path formed by the exhaust flow path forming unit 442. The nitrogen gas discharged from the gas discharge port 433 is guided rearward along the plate 437 and is exhausted from the exhaust port 441.

The removal apparatus 400 further includes a power supply 445. The power supply 445 is disposed in a region extending from the center of the lower space 416 in the Y direction to the rear side. The power supply 445 is connected to the ultraviolet lamp 431 via a cable 446. The ultraviolet lamp 431 emits light by the supply of power from the power supply 445. The removal apparatus 400 includes a fan 449 for cooling the power supply 445. The fan 449 is disposed behind the power supply 445. The air flow generated by the fan 449 flows into the exhaust flow path of the exhaust flow path forming unit 443.

In addition, an exhaust port 447 is provided in a wall on the rear side of the housing 411. The exhaust port 447 is connected to the exhaust flow path of the exhaust flow path forming unit 444. Particles generated from each part of the substrate holding unit 405, which is located in the lower space 416, are removed by riding on an exhaust flow toward the exhaust port 447. The plate 414 is provided with a slit 417 that causes the upper space 415 and the lower space 416 to communicate with each other. The gas and/or particles in the upper space 415 are exhausted from the exhaust port 447 through the slit 417.

The substrate holding unit 405 includes a moving mechanism 451 and a substrate transfer unit 406. The moving mechanism 451 is disposed in the lower space 416. The substrate transfer unit 406 is disposed in the upper space 415. The moving mechanism 451 is configured to move the substrate transfer unit 406 along the X direction and to lift and lower the substrate transfer unit 406.

The moving mechanism 451 includes a slider 453, a lift mechanism 454, and a horizontal moving mechanism 455. The horizontal moving mechanism 455 extends long in the X direction in the lower space 416 and is provided in front of the power supply 445. The horizontal moving mechanism 455 includes a ball screw and a guide rail connected to the slider 453, and a motor. The slider 453 moves in the X direction by the rotation of the ball screw by the motor.

The lift mechanism 454 is disposed on the slider 453. The lift mechanism 454 includes a motor 457 and a support 458. The support 458 includes a ball screw and a guide rail that extend in the vertical direction. The support 458 extends from the lower space 416 to the upper space 415 through the slit 417. The substrate transfer unit 406 is connected to the support 458 in the upper space 415.

The substrate transfer unit 406 includes a moving plate 461 and a holding ring 463. The moving plate 461 is a horizontal plate formed in a square shape. The moving plate 461 is provided with a circular opening 462. The ball screw and the guide rail constituting the support 458 of the moving mechanism 451 are connected to the moving plate 461 outside the opening 462. The substrate transfer unit 406 vertically moves along the guide rail by the rotation of the ball screw by the motor 457.

The substrate transfer unit 406 further includes the holding ring 463. The holding ring 463 is supported by an inner peripheral edge of the moving plate 461 that defines the opening 462. A thickness of the holding ring 463 is larger than a thickness of an inner peripheral edge of the moving plate 461. The holding ring 463 defines a circular region 464 inside the holding ring 463. The substrate W is disposed in the circular region 464. A plurality of substrate holders 471 are attached to the holding ring 463. The plurality of substrate holders 471 support the substrate W disposed in the circular region 464 and on the circular region 464. An inner peripheral surface 465 of the holding ring 463 faces the side surface of the substrate W disposed in the circular region 464. The holding ring 463 surrounds the substrate W to restrict the position of the edge of the substrate W, and prevents the substrate W from being separated and falling from the substrate transfer unit 406.

A position of the center of the circular region 464 in the Y direction coincides with a position of the center of the spin chuck 421 in the Y direction. The substrate transfer unit 406 is moved in the X direction by the moving mechanism 451 between a position where the center of the circular region 464 overlaps the center of the spin chuck 421 (this position may be referred to as a “delivery position”) and a position where the center of the circular region 464 is disposed behind the window 432.

The substrate transfer unit 406 further includes a plurality of light shielding plates 466. The plurality of light shielding plates 466 extend from a plurality of (for example, four) regions that are spaced apart from each other in the circumferential direction at a lower end of the inner peripheral surface 465 of the holding ring 463 toward the center of the circular region 464. The plurality of light shielding plates 466 extend below the substrate W disposed in the circular region 464. The plurality of light shielding plates 466 suppresses the light from reaching an upper surface side of the substrate W and the O₃ gas generated by irradiating the organic layer WL with the light from reaching the upper surface of the substrate W. The plurality of light shielding plates 466 are close to each other and extend along the circumferential direction such that an aggregate of the plurality of light shielding plates 466 substantially forms an annular plate.

A circular pad 472 is provided on an upper portion of a tip end of each of the plurality of substrate holders 471. The pad 472 provides a suction port 473. The suction port 473 is connected to the exhaust source 420 via a pipe 474 and a valve V42. In a state in which the valve V42 is closed, the substrate W is sucked into the suction port 473 and is held by the pad 472.

The holding ring 463 is provided with an annular flow path 483 therein. The annular flow path 483 is connected to the gas source 436 of the nitrogen gas via a flow rate regulator 484 and a pipe 485. The holding ring 463 further provides a plurality of gas flow paths 486. Each of the plurality of gas flow paths 486 extends from the annular flow path 483 to the inner peripheral edge of the holding ring 463, and a gas discharge port 487 is provided at the inner peripheral edge. The nitrogen gas discharged from the gas discharge port 487 of each of the plurality of gas flow paths 486 flows downward through a gap between the substrate W and each of the plurality of light shielding plates 466. Accordingly, the flow of the O₃ gas from below the substrate W toward the upper surface of the substrate W is suppressed.

The removal apparatus 400 further includes a controller 500. The controller 500 consists of, for example, a computer, and stores a program in a storage thereof. This program incorporates a set of program instructions that enable a series of operations in the removal apparatus 400 to be performed. The controller 500 executes the program to send a control signal to each part of the removal apparatus 400. Accordingly, each part of the removal apparatus 400 is controlled. The controller 2 described above may also serve as the controller 500.

According to the removal apparatus 400, the organic layer WL can be removed by irradiating the organic layer WL formed on the back surface Wr of the substrate W with light.

The description will be made with reference to FIG. 8 again. In each step of the method MTA, each part of the substrate processing system PS may be controlled by the controller CU. As illustrated in FIG. 8, the method MTA includes Step STd, Step STe, and Step STf in addition to the Step STa, Step STb, and Step STc described above.

Step STd is performed before Step STa. In Step STd, the organic layer WL is formed. The organic layer WL is formed using the film forming apparatus 200. That is, the organic layer WL is formed in an apparatus different from the substrate processing apparatus such as the plasma processing apparatus 1 that processes the substrate W in Step STc.

As described above, the organic layer WL may be formed on the entire back surface Wr. Alternatively, the organic layer WL may be partially formed on the back surface Wr. The organic layer WL is partially formed on the back surface Wr by masking a region in which the organic layer WL is not formed in the back surface Wr during the formation of the organic layer WL using the film forming apparatus 200. Alternatively, the organic layer WL may be formed on the back surface Wr using the film forming apparatus 200 and then partially removed from the back surface Wr using a removal apparatus such as the removal apparatus 400.

As described above, the organic layer WL may be formed in the central region of the back surface Wr or may be formed in the outer region of the back surface Wr. The organic layer WL may not be formed in the plurality of regions Wp. The plurality of regions Wp are masked by abutting the regions with the plurality of gap pins 223 during the formation of the organic layer WL in the film forming apparatus 200. The organic layer WL may not be formed in a region of the back surface Wr with which a pick of a transfer device (for example, various transfer robots) comes into contact during transfer of the substrate W.

Step STe is performed after Step STd and before Step STa. In Step STe, the substrate W is transferred into the chamber 10. That is, the substrate W having the organic layer WL is transferred into the chamber of the substrate processing apparatus such as the plasma processing apparatus 1 that processes the substrate W in Step STc. In a case where any of the process modules PM1 to PM6 is used in Step STc in the substrate processing system PS illustrated in FIG. 9, the substrate W is transferred into the chamber via the transfer robot TR3 and the transfer robot TR1. In a case where any of the process modules PM7 to PM12 is used in Step STc in the substrate processing system PS illustrated in FIG. 9, the substrate W is transferred into the chamber via the transfer robot TR3, the transfer robot TR1, and the transfer robot TR2.

The subsequent Step STa to Step STc are performed in a substrate processing apparatus such as the plasma processing apparatus 1 that processes the substrate W. After that, the substrate W is transferred to the removal apparatus 400. Then, Step STf is performed. Step STf is performed using the removal apparatus 400. In Step STf, the organic layer WL is removed by irradiating the organic layer WL with light in the removal apparatus 400.

The film forming apparatus 200 and/or the removal apparatus 400 may be connected to the chamber of the transfer module TM1 or TM2. Alternatively, the film forming apparatus 200 and/or the removal apparatus 400 may be connected to the chamber of the loader module LM instead of the aligner AN or the storage SR. Alternatively, the film forming apparatus 200 and/or the removal apparatus 400 may be disposed in the aligner AN or the storage SR. Alternatively, the film forming apparatus 200 and/or the removal apparatus 400 may be connected to the chamber of the transfer module TM1 or the chamber of TM2, instead of the process module other than the process module used in Step STc among the process modules PM1 to PM12. Alternatively, the film forming apparatus 200 and/or the removal apparatus 400 may be disposed in the chamber of the process module used in Step STc among the process modules PM1 to PM12.

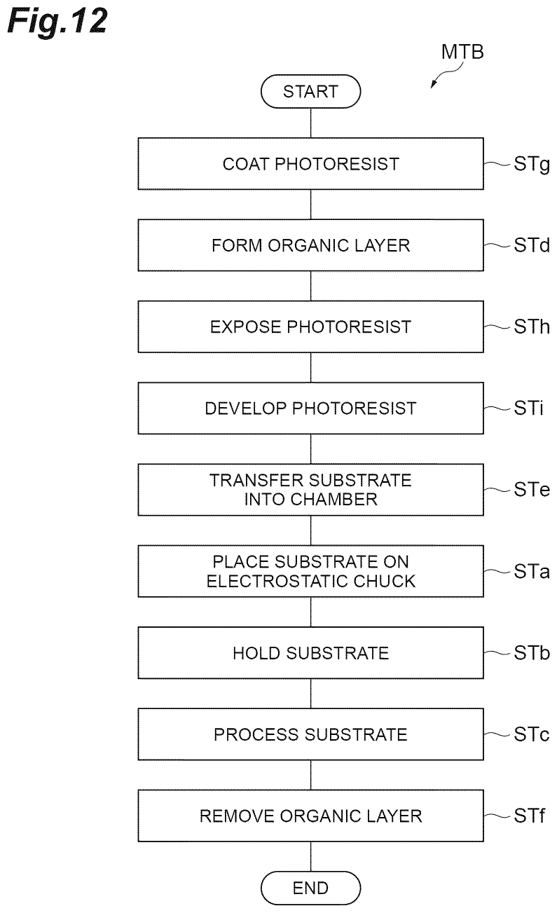

In the following, still another example embodiment will be described with reference to FIG. 12. FIG. 12 is a flowchart illustrating a substrate processing method according to still another example embodiment. In the following, the substrate processing method illustrated in FIG. 12 (hereinafter, referred to as a “method MTB”) will be described from the viewpoint of differences from the method MTA. The method MTB is performed in the substrate processing system.

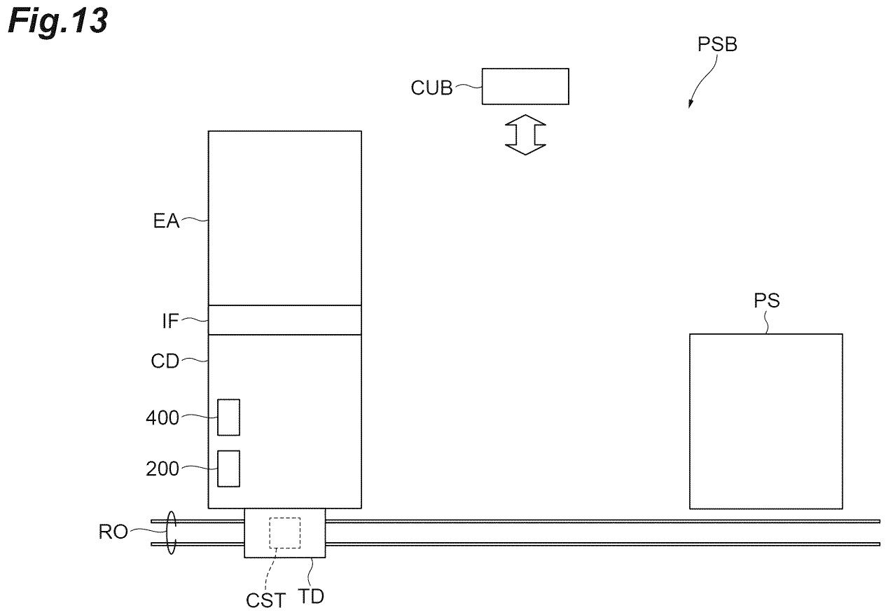

FIG. 13 is a diagram illustrating substrate processing equipment according to another example embodiment. Substrate processing equipment PSB illustrated in FIG. 13 may be used in the method MTB. The substrate processing equipment PSB is a substrate processing system, and includes a coating development apparatus CD, an exposure apparatus EA, and a substrate processing system PS.

The substrate processing equipment PSB may further include a transfer path RO and a transfer device TD. The transfer device TD is configured to move along the transfer path RO and transfer the cassette CST. The transfer device TD may be a ceiling traveling vehicle such as an Overhead Hoist Transfer. The transfer device TD transfers the cassette CST to the coating development apparatus CD and also transfers the cassette CST to any of the load ports LP1 to LP4 of the substrate processing system PS.

The coating development apparatus CD is configured to receive therein the substrate W in the cassette CST and to coat the upper surface of the substrate W with a photoresist. The coating development apparatus CD is connected to the exposure apparatus EA via an interface IF. The exposure apparatus EA is configured to expose the photoresist of the substrate W. The coating development apparatus CD is configured to develop the photoresist of the substrate W exposed in the exposure apparatus EA.

As illustrated in FIG. 13, the substrate processing equipment PSB further includes the film forming apparatus 200 and the removal apparatus 400 described above. In the example illustrated in FIG. 13, the film forming apparatus 200 and the removal apparatus 400 are disposed in the coating development apparatus CD, not in the substrate processing system PS. The film forming apparatus 200 and/or the removal apparatus 400 may be disposed in the exposure apparatus EA.

The substrate processing equipment PSB further includes a controller CUB. The controller CUB is, for example, a computer. The controller CUB includes a central processing unit (CPU), a random access memory (RAM), a read only memory (ROM), an auxiliary storage device, and the like. The CPU operates based on a program stored in a ROM or an auxiliary storage device and controls each part of the substrate processing equipment PSB. Alternatively, the controller 2 may also serve as the controller CUB.

The description will be made with reference to FIG. 12 again. In each step of the method MTB, each part of the substrate processing system PS may be controlled by the controller CUB. As illustrated in FIG. 12, the method MTB further includes Step STg to Step STi in addition to Step STa to Step STf.

Step STg may be performed before Step STd. In Step STg, the photoresist is applied to the upper surface of the substrate W. The photoresist is applied to the upper surface of the substrate W in the coating development apparatus CD.

Next, as described above in relation to the method MTA, in Step STd, the organic layer WL is formed on the back surface Wr of the substrate W in the film forming apparatus 200. Step STd may be performed before Step STg.

Next, Step STh is performed. In Step STh, the photoresist of the substrate W is exposed. The photoresist is exposed in the exposure apparatus EA. Step STh may be performed before Step STd.

Next, Step STi is performed. In Step STi, the photoresist is developed. The photoresist is developed in the coating development apparatus CD. Step STi may be performed before Step STd.

Next, the substrate W is transferred by the transfer device TD to any of the load ports LP1 to LP4 of the substrate processing system PS. Thereafter, in Step STe, the substrate W is transferred into a chamber of a process module which is a substrate processing apparatus such as the plasma processing apparatus 1 used in Step STc among the process modules PM1 to PM12. Then, in the process module, Step STa to Step STc are performed. After that, the substrate W is transferred to the removal apparatus 400. Then, in Step STf, the organic layer WL is removed in the removal apparatus 400.

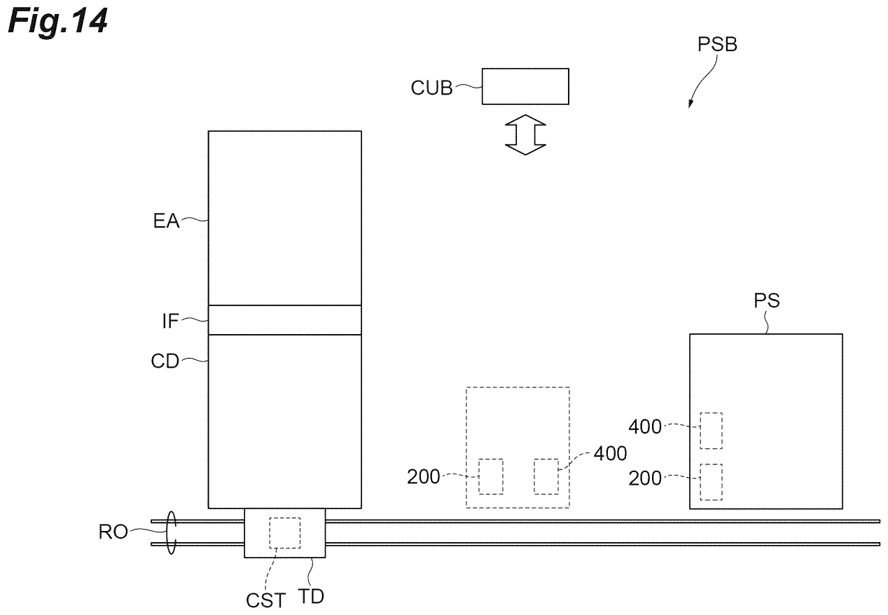

In the following, the description will be made with reference to FIG. 14. FIG. 14 is a diagram illustrating substrate processing equipment according to still another example embodiment. The method MTB may be performed in substrate processing equipment PSB (or substrate processing system) illustrated in FIG. 14. As illustrated in FIG. 14, the film forming apparatus 200 and/or the removal apparatus 400 may be separated from the coating development apparatus CD, the exposure apparatus EA, and the substrate processing system PS, or may be configured to receive the substrate W from the cassette CST transferred by the transfer apparatus TD. Alternatively, the film forming apparatus 200 and/or the removal apparatus 400 may be provided in the substrate processing system PS as described above. Alternatively, the film forming apparatus 200 may be disposed in the coating development apparatus CD, and the removal apparatus 400 may be disposed in the substrate processing system PS. Alternatively, the film forming apparatus 200 may be disposed in the coating development apparatus CD, and the removal apparatus 400 may be separated from the coating development apparatus CD, the exposure apparatus EA, and the substrate processing system PS, and may be configured to receive the substrate W from the cassette CST transferred by the transfer device TD.

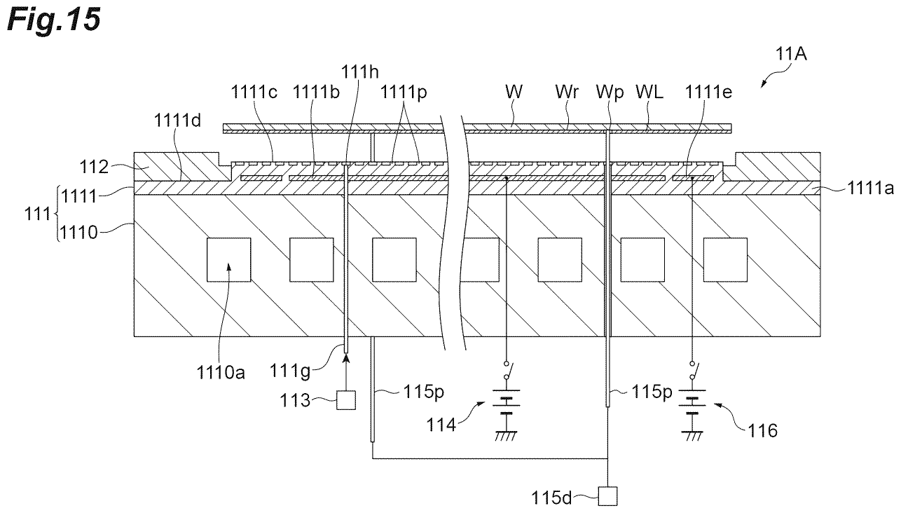

In the following, the description will be made with reference to FIG. 15. FIG. 15 is a cross-sectional view illustrating a substrate support according to another example embodiment. The plasma processing apparatus 1 used in Step STc may include a substrate support 11A illustrated in FIG. 15 instead of the substrate support 11. In the following, the substrate support 11A will be described from the viewpoint of the difference from the substrate support 11.

The electrostatic chuck 1111 of the substrate support 11A includes an electrostatic electrode 1111e in addition to the electrostatic electrode 1111b. The electrostatic electrode 1111e extends in the ceramic member 1111a to be separated from the electrostatic electrode 1111b and to surround the electrostatic electrode 1111b. The electrostatic electrode 1111b is disposed to be located below a central portion of the substrate W placed on the substrate support surface 1111c. The electrostatic electrode 1111e is disposed to be located below an outer portion (for example, an edge region) with respect to a central portion of the substrate W placed on the substrate support surface 1111c. The electrostatic electrode 1111b may have a circular shape, and the electrostatic electrode 1111e may have an annular shape. A DC power supply 116 is connected to the electrostatic electrode 1111e via a switch.

In a case where the substrate support 11A is used, in Step STb, after the central portion of the substrate W is held, the outer portion (for example, the edge region) of the substrate W may be held. That is, in Step STb, after the voltage from the DC power supply 114 is applied to the electrostatic electrode 1111b, the voltage from the DC power supply 116 may be applied to the electrostatic electrode 1111e. By holding the substrate W in such Step STb, friction of the substrate W with respect to the substrate support surface 1111c is suppressed.

While various exemplary embodiments have been described above, various additions, omissions, substitutions and changes may be made without being limited to the example embodiments described above. Elements of the different embodiments may be combined to form another embodiment.

For example, in Step STa to Step STc, a substrate processing apparatus other than the plasma processing apparatus 1 may be used. In addition, the processing performed on the substrate W in Step STc may be plasma processing or substrate processing different from plasma etching. In addition, the method MTA and the method MTB may not include Step STf.

Here, various example embodiments included in the disclosure is described in the following [E1] to [E19].
[E1]

A substrate processing method comprising:
placing a substrate on an electrostatic chuck of a substrate support of a substrate processing apparatus, the electrostatic chuck including a substrate support surface, the substrate including a back surface and an organic layer formed in advance on the back surface, and the substrate being placed on the electrostatic chuck so that the organic layer is in contact with the substrate support surface;
operating the electrostatic chuck to hold the substrate by electrostatic attraction; and
processing the substrate in the substrate processing apparatus.
[E2]

The substrate processing method according to E1, wherein
the organic layer has a friction coefficient lower than a friction coefficient of the back surface of the substrate.
[E3]

The substrate processing method according to E1 or E2, wherein
the substrate support has a gas supply port configured to supply a heat transfer gas to a gap between the substrate and the electrostatic chuck.
[E4]

The substrate processing method according to any one of E1 to E3, further comprising:
forming the organic layer on the back surface of the substrate in a film forming apparatus, the film forming apparatus being an apparatus different from the substrate processing apparatus that includes a chamber and the substrate support in the chamber; and
transferring the substrate into the chamber of the substrate processing apparatus after the forming of the organic layer and before the placing of the substrate.
[E5]

The substrate processing method according to E4, wherein
the film forming apparatus is in a coating development apparatus or an exposure apparatus used in lithography for the substrate.
[E6]

The substrate processing method according to E5, wherein
the organic layer is formed before exposure of a photoresist formed on the substrate using the exposure apparatus.

[E7]

The substrate processing method according to any one of E1 to E6, wherein
the organic layer includes silicon and carbon.

[E8]

The substrate processing method according to any one of E1 to E7, wherein
a film forming gas used for forming the organic layer substitutes a silanol group on the back surface of the substrate with a hydrophobic group containing carbon.
[E9]

The substrate processing method according to any one of E1 to E8, wherein
the organic layer is a monomolecular layer.

[E10]

The substrate processing method according to any one of E1 to 19, wherein
in the holding of the substrate, a portion of the substrate outside a central portion of the substrate is held by the electrostatic chuck after the central portion of the substrate is held by the electrostatic chuck.
[E11]

The substrate processing method according to any one of E1 to E10, wherein
the substrate processing apparatus further includes a support body configured to be movable up and down with respect to the substrate support surface and to support the substrate at a position spaced above the substrate support surface, and
the organic layer is formed in a region other than a region in the back surface of the substrate on which the support body abuts.
[E12]

The substrate processing method according to any one of E1 to E11, wherein
the processing of the substrate includes performing plasma processing on the substrate.
[E13]

A substrate processing apparatus comprising:
a chamber;
a substrate support that is in the chamber and includes an electrostatic chuck having a substrate support surface; and
a controller configured to perform
   placing a substrate on the electrostatic chuck, the substrate including a back surface and an organic layer formed in advance on the back surface, and the substrate being placed on the electrostatic chuck so that the organic layer is in contact with the substrate support surface,
   controlling the electrostatic chuck to hold the substrate by electrostatic attraction, and
   processing the substrate in the chamber.

[E14]

A substrate processing system comprising:
a plasma processing apparatus which is the substrate processing apparatus according to E13;
a film forming apparatus configured to form the organic layer; and
a removal apparatus configured to remove the organic layer.

[E15]

A substrate processing system comprising:
the substrate processing apparatus according to E13; and
a film forming apparatus configured to form the organic layer, wherein
the film forming apparatus includes
   a film forming chamber,
   a support body configured to support the substrate in the film forming chamber,
   a first gas supply port that is at a position facing a center of an upper surface of the substrate supported by the support body of the film forming apparatus and that is configured to supply an inert gas toward the center of the upper surface,
   a second gas supply port that is at a position facing an edge region of the upper surface of the substrate supported by the support body of the film forming apparatus and that is configured to supply the inert gas toward the edge region,
   a third gas supply port that is at a position facing the back surface of the substrate supported by the support body of the film forming apparatus and that is configured to supply a film forming gas for forming the organic layer to the back surface, and
   an exhaust port that is outside an edge of the substrate and configured to exhaust a gas in the film forming chamber.
[E16]

The substrate processing system according to E15, further comprising:
a removal apparatus configured to remove the organic layer after the processing of the substrate.
[E17]

The substrate processing system according to E16, wherein
the controller is configured to perform
   forming the organic layer on the back surface of the substrate in the film forming apparatus,
   subsequently transferring the substrate to the substrate processing apparatus,
   subsequently holding the substrate by the electrostatic chuck,
   subsequently processing the substrate in the substrate processing apparatus, and
   subsequently removing the organic layer in the removal apparatus.
[E18]

The substrate processing system according to E16, further comprising:
a coating development apparatus configured to perform coating and development of a photoresist; and
an exposure apparatus configured to expose the photoresist,
wherein the controller is configured to perform
   forming the organic layer on the back surface of the substrate in the film forming apparatus,
   subsequently exposing the photoresist in the exposure apparatus,
   subsequently developing the photoresist in the coating development apparatus,
   subsequently transferring the substrate to the substrate processing apparatus,
   subsequently holding the substrate by the electrostatic chuck,
   subsequently processing the substrate in the substrate processing apparatus, and
   subsequently removing the organic layer in the removal apparatus.
[E19]

The substrate processing system according to E17 or E18, wherein
the substrate processing apparatus is an etching apparatus configured to perform etching on the substrate.
[E20]

The substrate processing system according to E17 to E19, further comprising:
a loader module configured to transfer the substrate between a cassette in which the substrate is accommodated and a load lock module that provides a preliminary decompression chamber; and
a transfer module configured to provide a decompressed space between the load lock module and the substrate processing apparatus and transfer the substrate through the decompressed space,
wherein the film forming chamber of the film forming apparatus is connected to the loader module or the transfer module.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing method comprising:
placing a substrate on an electrostatic chuck of a substrate support of a substrate processing apparatus, the electrostatic chuck including a substrate support surface, the substrate including a back surface and an organic layer formed in advance on the back surface, and the substrate being placed on the electrostatic chuck so that the organic layer is in contact with the substrate support surface;
operating the electrostatic chuck to hold the substrate by electrostatic attraction; and
processing the substrate in the substrate processing apparatus.

2. The substrate processing method according to claim 1, wherein
the organic layer has a friction coefficient lower than a friction coefficient of the back surface of the substrate.

3. The substrate processing method according to claim 1, wherein
the substrate support has a gas supply port configured to supply a heat transfer gas to a gap between the substrate and the electrostatic chuck.

4. The substrate processing method according to claim 1, further comprising:
forming the organic layer on the back surface of the substrate in a film forming apparatus, the film forming apparatus being an apparatus different from the substrate processing apparatus that includes a chamber and the substrate support in the chamber; and
transferring the substrate into the chamber of the substrate processing apparatus after the forming of the organic layer and before the placing of the substrate.

5. The substrate processing method according to claim 4, wherein
the film forming apparatus is in a coating development apparatus or an exposure apparatus used in lithography for the substrate.

6. The substrate processing method according to claim 5, wherein
the organic layer is formed before exposure of a photoresist formed on the substrate using the exposure apparatus.

7. The substrate processing method according to claim 1, wherein
the organic layer includes silicon and carbon.

8. The substrate processing method according to claim 1, wherein
a film forming gas used for forming the organic layer substitutes a silanol group on the back surface of the substrate with a hydrophobic group containing carbon.

9. The substrate processing method according to claim 1, wherein
the organic layer is a monomolecular layer.

10. The substrate processing method according to claim 1, wherein
in the holding of the substrate, a portion of the substrate outside a central portion of the substrate is held by the electrostatic chuck after the central portion of the substrate is held by the electrostatic chuck.

11. The substrate processing method according to claim 1, wherein
the substrate processing apparatus further includes a support body configured to be movable up and down with respect to the substrate support surface and to support the substrate at a position spaced above the substrate support surface, and
the organic layer is formed in a region other than a region in the back surface of the substrate on which the support body abuts.

12. The substrate processing method according to claim 1, wherein
the processing of the substrate includes performing plasma processing on the substrate.

13. A substrate processing apparatus comprising:
a chamber;
a substrate support that is in the chamber and includes an electrostatic chuck having a substrate support surface; and
a controller configured to perform
placing a substrate on the electrostatic chuck, the substrate including a back surface and an organic layer formed in advance on the back surface, and the substrate being placed on the electrostatic chuck so that the organic layer is in contact with the substrate support surface,
controlling the electrostatic chuck to hold the substrate by electrostatic attraction, and
processing the substrate in the chamber.

14. A substrate processing system comprising:
a plasma processing apparatus which is the substrate processing apparatus according to claim 13;
a film forming apparatus configured to form the organic layer; and
a removal apparatus configured to remove the organic layer.

15. A substrate processing system comprising:
the substrate processing apparatus according to claim 13; and
a film forming apparatus configured to form the organic layer, wherein
the film forming apparatus includes
a film forming chamber,
a support body configured to support the substrate in the film forming chamber,
a first gas supply port that is at a position facing a center of an upper surface of the substrate supported by the support body of the film forming apparatus and that is configured to supply an inert gas toward the center of the upper surface,
a second gas supply port that is at a position facing an edge region of the upper surface of the substrate supported by the support body of the film forming apparatus and that is configured to supply the inert gas toward the edge region,
a third gas supply port that is at a position facing the back surface of the substrate supported by the support body of the film forming apparatus and that is configured to supply a film forming gas for forming the organic layer to the back surface, and
an exhaust port that is outside an edge of the substrate and configured to exhaust a gas in the film forming chamber.

16. The substrate processing system according to claim 15, further comprising:
a removal apparatus configured to remove the organic layer after the processing of the substrate.

17. The substrate processing system according to claim 16, wherein
the controller is configured to perform
forming the organic layer on the back surface of the substrate in the film forming apparatus,
subsequently transferring the substrate to the substrate processing apparatus,
subsequently holding the substrate by the electrostatic chuck,
subsequently processing the substrate in the substrate processing apparatus, and
subsequently removing the organic layer in the removal apparatus.

18. The substrate processing system according to claim 16, further comprising:
a coating development apparatus configured to perform coating and development of a photoresist; and
an exposure apparatus configured to expose the photoresist,
wherein the controller is configured to perform
forming the organic layer on the back surface of the substrate in the film forming apparatus,
subsequently exposing the photoresist in the exposure apparatus,
subsequently developing the photoresist in the coating development apparatus,
subsequently transferring the substrate to the substrate processing apparatus,
subsequently holding the substrate by the electrostatic chuck,
subsequently processing the substrate in the substrate processing apparatus, and
subsequently removing the organic layer in the removal apparatus.

19. The substrate processing system according to claim 17, wherein
the substrate processing apparatus is an etching apparatus configured to perform etching on the substrate.

20. The substrate processing system according to claim 17, further comprising:
a loader module configured to transfer the substrate between a cassette in which the substrate is accommodated and a load lock module that provides a preliminary decompression chamber; and
a transfer module configured to provide a decompressed space between the load lock module and the substrate processing apparatus and transfer the substrate through the decompressed space,
wherein the film forming chamber of the film forming apparatus is connected to the loader module or the transfer module.
